(19) United States
(12) Patent Application Publication
(10) Pub. No.: US 2015/0364387 A1
(43) Pub. Date: Dec. 17, 2015

(54) WAFER POLISHING METHOD

(71) Applicants: Moon-gi CHO, Gunpo-si (KR); Eun-chul AHN, Seoul (KR); Jung-ho CHOI, Cheonan-si (KR)

(72) Inventors: Moon-gi CHO, Gunpo-si (KR); Eun-chul AHN, Seoul (KR); Jung-ho CHOI, Cheonan-si (KR)

(21) Appl. No.: 14/729,034

(22) Filed: Jun. 2, 2015

(30) Foreign Application Priority Data
Jun. 13, 2014 (KR) 10-2014-0072297

(51) Int. Cl. H01L 21/66; H01L 21/306; H01L 21/02; H01L 21/304

(52) U.S. Cl. CPC H01L 22/20; H01L 22/12; H01L 21/304; H01L 21/30625; H01L 21/02057; H01L 21/02016; H01L 21/02013

(57) ABSTRACT

A wafer polishing method includes first polishing for polishing a wafer backside of a wafer, detecting if a defect exists on the wafer backside, determining whether a level of the detected defect is not within an allowable range, if a defect exists on the wafer backside, and second polishing for repolishing the wafer backside if the level of the defect is within an allowable range. Accordingly, a wafer may be reprocessed so that a level of defects, which may be caused by performing grinding and polishing on the wafer backside, is within an allowable range. Thus, the wafer backside may have uniform quality, and a failure rate of the wafer during a manufacturing processed may be efficiently decreased.

### CROSS-REFERENCE TO RELATED APPLICATION

This application claims priority to Korean Patent Application No. 10-2014-0072297, filed on Jun. 13, 2014, in the Korean Intellectual Property Office, the disclosure of which is incorporated herein in its entirety by reference.

### BACKGROUND

1. Technical Field

The inventive concept relates to a wafer polishing method, and more particularly, to a wafer backside polishing method.

2. Discussion of Related Art

In a wafer manufacturing process for forming a semiconductor integrated circuit (IC) on a wafer, a wafer having a large thickness is used to reduce damages to the wafer which may occur while the wafer is moved or treated.

Accordingly, a wafer backside is polished to remove an unnecessary part of the wafer before a semiconductor package is manufactured after a wafer manufacturing process is performed. Thus, a size of a semiconductor chip may be reduced, and fine heat dissipation characteristics may be ensured by polishing the wafer backside.

### SUMMARY

According to an embodiment of the inventive concept, a failure rate of a wafer which occurs in a process of polishing a wafer backside may be reduced.

According to an embodiment of the inventive concept, there is provided a wafer polishing method including: a first polishing for polishing a wafer backside of a wafer; detecting a defect that existed on the wafer backside; determining whether a level of the detected defect is outside of an allowable range; and a second polishing for repolishing the wafer backside, if the level of the detected defect is outside of the allowable range.

The wafer may be unloaded if the level of the detected defect is within the allowable range.

The wafer polishing method may further include re-detecting a defect that existed on the wafer backside of wafer after the second polishing is performed, and unloading the wafer into a normal wafer housing unit if the level of the re-detected defect is within the allowable range, and unloading the wafer into a defective wafer housing unit if the level of the re-detected defect is out of the allowable range.

The defect may be at least one selected from the group consisting of a pit, a scratch, and a particle.

The defect may be a thickness non-uniformity of a gettering layer.

A polishing system for performing the wafer polishing method may be equipped with a metrology device, and the detecting of the defect may be performed by using the metrology device.

The detecting of the defect may be performed via an arm equipped in a polishing system and a metrology device installed in an arm's area facing the wafer backside.

The detecting of the defect may be performed by irradiating light on the wafer backside and analyzing reflected light.

A first polishing apparatus for performing the first polishing and a second polishing apparatus for performing the second polishing may each include a first polishing pad and a second polishing pad, and a degree of abrasion of the first polishing pad is different from a degree of abrasion of the second polishing pad.

A first polishing time taken for performing the first polishing may be different from a second polishing time taken for performing the second polishing.

The wafer polishing method may further include grinding before performing the first polishing.

The grinding may be performed for several times, and a degree of abrasion of grinding pads, used for the performing of the grinding for several times, may be different from each other.

A first slurry used for the first polishing may be different from a second slurry used for the second polishing.

The wafer polishing method may further include cleaning of the wafer after the first polishing is performed.

According to another aspect of the inventive concept, there is provided a wafer polishing method including: polishing a wafer backside of a wafer on a polishing table; detecting a defect that existed on the wafer backside; determining whether a level of the detected defect is out of an allowable range; repolishing the wafer backside if the level of the detected defect is out of the allowable range; and repeating the detecting, the determining, and the re-polishing until it is determined that a level of a detected defect on the wafer backside is within the allowable range.

The wafer may be unloaded if the level of the detected defect is within the allowable range.

In the repeating of the detecting, the determining, and the re-polishing, it may be determined whether the level of the detected defect is within a critical range so the wafer may be reprocessed into being in the allowable range by performing the re-polishing if it is determined that the level of the detected defect on the wafer backside is not within the allowable range.

A polishing time taken for performing the polishing may be different from a repolishing time taken for performing the repolishing.

The defect may be at least one selected from the group consisting of a pit, a scratch, and a particle.

The defect may be about a thickness non-uniformity of a gettering layer.

According to an aspect of the inventive concept, there is provided a wafer polishing method including: a first polishing for polishing a first wafer backside by a first polishing pad equipped in a polishing system; detecting a defect that existed on the first wafer backside by a metrology device equipped in the polishing system]; determining whether the level of the detected defect is out of an allowable range; and a second polishing for repolishing the first wafer backside by a second polishing pad equipped in the polishing system, if the level of the detected defect is out of the allowable range; and wherein the first polishing for polishing a second wafer backside by the first polishing pad while the second polishing for repolishing the first wafer backside by the second polishing pad.

### BRIEF DESCRIPTION OF THE DRAWINGS

Exemplary embodiments of the inventive concept will be more clearly understood from the following detailed description taken in conjunction with the accompanying drawings in which:

FIG. 1 is a flowchart for explaining a wafer backside polishing method according to embodiments of the inventive concept;

FIG. 2 is a plan view of a polishing system used in the wafer backside polishing method described with reference to FIG. 1 according to an embodiment;

FIG. 3 is a cross-sectional view for explaining a process that corresponds to polishing included in the wafer backside polishing method described with reference to FIG. 1 according to an embodiment;

FIGS. 4A and 4B are flowcharts of defect detection in the wafer backside polishing method described with reference to FIG. 1 according to an embodiment;

FIGS. 5A and 5B are schematic cross-sectional views of defect metrology devices used in the wafer backside defect detections described with reference to FIGS. 4A and 4B according to an embodiment;

FIG. 6 is a cross-sectional view for explaining a process that corresponds to operations performed after first polishing in the wafer backside polishing method described with reference to FIG. 1 according to an embodiment;

FIG. 7 is a flowchart of a wafer backside polishing method according to embodiments of the inventive concept;

FIG. 8 is a plan view of a polishing system used in the wafer backside polishing method described with reference to FIG. 7 according to an embodiment;

FIG. 9 is a cross-sectional view for explaining a process that corresponds to operations performed after first polishing in the wafer backside polishing method described with reference to FIG. 7 according to an embodiment;

FIG. 10 is a flowchart of a wafer backside polishing method according to embodiments of the inventive concept;

FIG. 11 is a plan view of a polishing system employed in the wafer backside polishing method described with reference to FIG. 10 according to an embodiment;

FIG. 12 is a cross-sectional view for explaining a process that corresponds to operations performed after polishing in the wafer backside polishing method described with reference to FIG. 10 according to an embodiment;

FIG. 13 is a flowchart for explaining a wafer backside polishing method according to embodiments of the inventive concept;

FIG. 14 is a plan view of a polishing system used in the wafer backside polishing method described with reference to FIG. 12 according to an embodiment; and

FIG. 15 is a cross-sectional view for explaining a process that corresponds to operation performed after polishing in the wafer backside polishing method described with reference to FIG. 12 according to an embodiment.

### DETAILED DESCRIPTION OF THE EMBODIMENTS

As used herein, the term “and/or” includes any and all combinations of one or more of the associated listed items. Expressions such as “at least one of,” when preceding a list of elements, modify the entire list of elements and do not modify the individual elements of the list.

Hereinafter, the inventive concept will be described more fully with reference to the accompanying drawings, in which exemplary embodiments of the inventive concept are shown. Like reference numerals in the drawings denote like elements, and thus their description will be omitted.

The embodiments of the inventive concept are provided so that the inventive concept is fully explained to those skilled in the art. The inventive concept may, however, be embodied in many different forms and should not be construed as being limited to the embodiments set forth herein; rather, these embodiments are provided so that this disclosure will be thorough and complete, and will fully convey the concept of the inventive concept to those skilled in the art.

It will be understood that, although the terms first, second, etc. may be used herein to describe various members, components, regions, layers, sections, and/or elements, these members, parts, regions, layers, sections, and/or elements should not be limited by these terms. These terms do not refer to a particular order, rank, or superiority and are only used to distinguish one member, component, region, layer, section, or element from another member, component, region, layer, section, or element. Thus, a first member, component, region, layer, section, or element discussed below could be termed a second member, component, region, layer, section, or element without departing from the teachings of the example embodiments. For example, a first element may be referred to as a second element, and similarly, a second element may be referred to as a first element without departing from the scope of protection.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, when an exemplary embodiment can be differently implemented, a function or an operation specified in a particular process may be performed differently from an order specified in a flowchart. For example, two continuous processes may be substantially simultaneously performed, or processes may be performed in a reverse order according to a related function or operation.

In the drawings, for example, illustrated shapes may be deformed according to fabrication technology and/or tolerances. Therefore, the exemplary embodiments are not limited to certain shapes illustrated in the present specification, and may include modifications of shapes caused in fabrication processes. The embodiments herein may be implemented in a specific form, or combined in various ways.

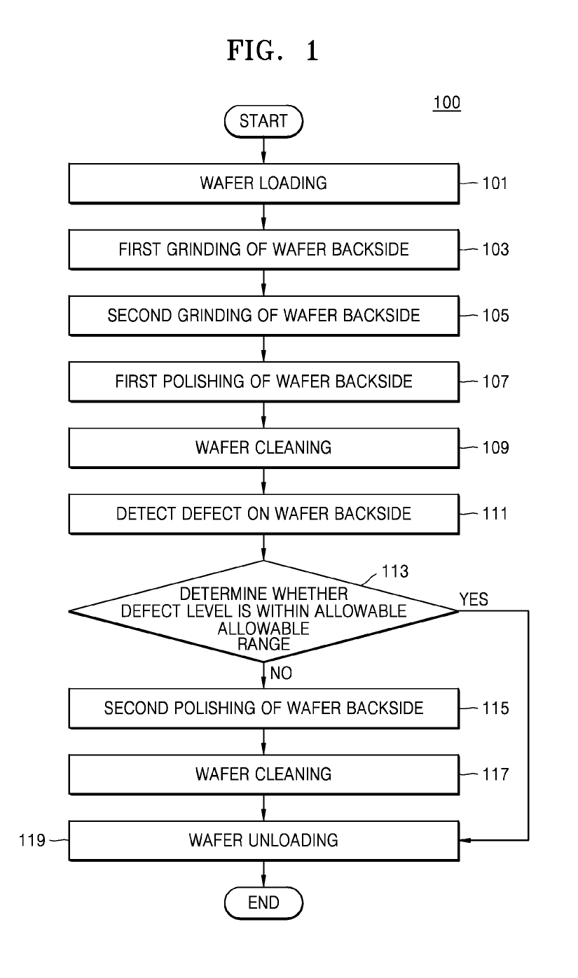

FIG. 1 is a flowchart of a wafer backside polishing method 100 according to embodiments of the inventive concept.

Referring to FIG. 1, in operation 101 of the wafer backside polishing method 100, a wafer is loaded on a polishing system. A wafer that standbys in a wafer supplying unit is placed on a standby table in the polishing system by a conveyor. Aligning of the wafer on the standby table so as to correctly place the wafer on the standby table may be performed. The aligned wafer is fixed onto the standby table by using vacuum adsorption.

In operation 103, the wafer placed on the standby table is moved to a first grinding table and first grinding is performed on a wafer backside. In the first grinding in the operation 103, grinding is performed on the wafer backside for the first time, and the wafer backside is roughly ground until the wafer reaches a certain extra thickness that is larger than a final target thickness.

In operation 105, second grinding is performed on the wafer backside on which the first grinding has been performed in the operation 103. In the operation 105, the wafer is ground more precisely than in the first grinding in the operation 103 until the wafer has the final target thickness.

In operation 107, first polishing is performed on the wafer backside on which the second grinding has been performed in the operation 105. The first polishing of the wafer backside performed in the operation 107 is a process of making the wafer backside like mirror-surface after the first grinding in the operation 103 and the second grinding in operation 105 have been performed so as to reduce warpage of the wafer to improve the strength of the wafer. The first polishing may be performed by chemical-mechanical polishing (CMP) to change the wafer backside into a mirror-flat shape by using a first polishing apparatus when a slurry is fed on the wafer.

In operation 109, the wafer on which the first polishing has been performed in the operation 107 is cleaned. The cleaning of the wafer is performed to remove the slurry that remained thereon after the first polishing performed in the operation 107 and byproducts generated in the operation 107.

In operation 111, it is detected if a defect on a backside of the wafer on which the cleaning has been performed in the operation 109 exists. The first grinding in the operation 103, the second grinding in the operation 105, and the first polishing in the operation 107 are processes of simply removing unnecessary parts of the wafer backside. However, many byproducts are caused on the wafer due to characteristics of the grinding processes performed in the operations 103, 105, and 107. Additionally, since a mechanical stress is constantly applied to the wafer on which the byproducts are deposited during operations of the grinding apparatus and the polishing system, various defects are formed on the wafer backside.

The defects may include a particle defect caused when a byproduct is inserted into the wafer, a pit defect caused when a groove is generated in the wafer due to a mechanical stress concentrated on the by-product, a scratch defect caused on the wafer when the wafer is rotated and a mechanical stress is applied to the byproduct on the wafer, or a crack defect caused when the wafer is broken due to any of the problems described above.

A pit defect and a scratch defect of a certain degree may prevent a foreign material, e.g. foreign metal, from penetrating into the wafer or prevent pollution of the wafer. As such, a metal pollution prevention layer formed on a wafer backside and including the pit defect or the scratch defect is referred to as a gettering layer.

Accordingly, a pit defect and a scratch defect formed on a wafer backside should not lead to generation of a crack of and penetration of a foreign material, e.g. foreign metal, into the wafer. A pit defect and a scratch defect are formed to such a degree that allows formation of a gettering layer, but they are formed unevenly, and thus, may cause an electrical fault.

Accordingly, the defect detection in the operation 111 may be performed to detect a particle defect, a pit defect, a scratch defect, or a non-uniformity of thickness of a gettering layer. In detail, the defect may relate to a depth or width of a pit defect, a depth, a length or a number of a scratch defect, a size or number of a particle defect, or non-uniformity of thickness of a gettering layer that extends over the wafer. In some embodiments, in the operation 111, the defect detection may be performed to detect defects regarding all elements that may affect a subsequent fabrication process or characteristics of a semiconductor device.

Since the defect detection may be performed by using a defect metrology device equipped in the polishing system, the defect detection may be performed inline via the polishing system after the first grinding in the operation 103, the second grinding in the operation 105, and the first polishing in the operation 107 are performed.

In some embodiments, the defect metrology device may employ various surface analysis methods such as photoelectron spectroscopy, auger electron spectroscopy, ion scattering, or secondary ion mass spectroscopy, and so on. The defect metrology device may detect a defect by irradiating particles such as an electrons, ions, light, or neutral atoms on a surface of the wafer so that the particles interact with the surface of the wafer 79B, or by scattering, absorption, penetration, or ionization caused by heat or an electric field.

Then, in operation 113, it is determined whether a level of the defect is within an allowable range. The allowable range of the level of the defect may be set by a user in consideration of a constituent material or a size of the wafer. For example, the allowable range of the level of the defect may be set so that a crack is not generated and a gettering layer has an even thickness. If it is determined that the level of the defect is within the allowable range, the wafer is treated as a normal wafer and unloaded into a wafer housing unit in operation 119.

If the level of the defect is not within the allowable range and it is determined that the wafer is a defective wafer, the wafer is treated as a defective wafer, and the second polishing of the wafer backside is performed in the operation 115. As the second polishing is performed on the wafer in the operation 115, since an entire surface of the wafer becomes even, and a level of the defect such as a particle defect, a pit defect, a scratch defect, and non-uniformity of thickness of the gettering layer may change. Thus, a defect level of the wafer is adjusted to be within the allowable range. Like the defect metrology device, a second polishing apparatus used for the second polishing may be equipped in the polishing system. Like the first polishing performed in the operation 107, the second polishing may be CMP.

In some embodiments, a first polishing time taken for performing the first polishing in the operation 107 may be equal to or different from a second polishing time taken for performing the second polishing in the operation 115. In other words, the first polishing time taken for performing the first polishing may be equal to or greater than the second polishing time taken for performing the second polishing or less than the second polishing time taken for performing the second polishing.

By performing the defect detection in the operation 111, the determining of whether the level of the defect is within the allowable range in the operation 113, and the second polishing in the operation 115, a defect on the wafer may be adjusted and controlled in real time. Thus, a failure rate of the wafer which may be caused in a process of processing the wafer backside may be remarkably decreased.

Then, in operation 117, the wafer on which the second polishing has been performed in the operation 115 is cleaned. As described above, the cleaning is performed to remove the slurry and by-products that remain on the wafer after the second polishing performed in the operation 115.

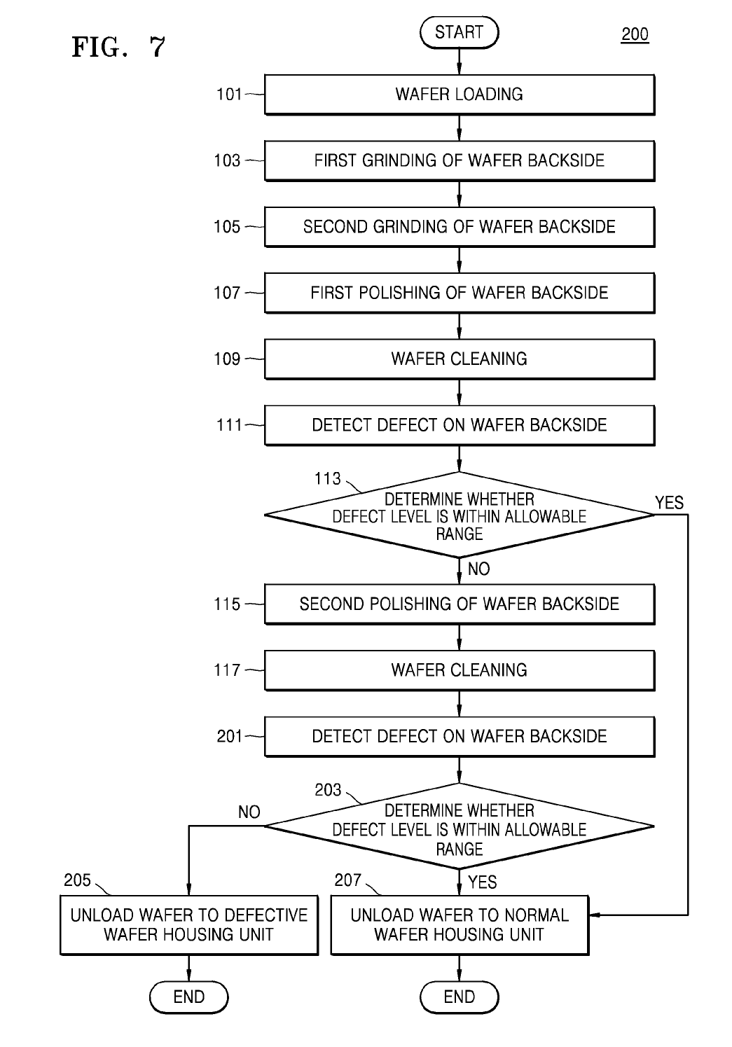

The wafer on which the second polishing in operation 115 and the cleaning in operation 117 are finished may be considered to be a normal wafer and unloaded into the wafer housing unit in operation 119. In FIG. 1, defect detection, which may be performed after the second polishing is performed in operation 115, is not shown. However, embodiments of the inventive concept are not limited thereto. In some embodiments, a defect detection may be additionally performed with respect to a surface of the wafer on which the second polishing in operation 115 and the cleaning in operation 117 have been performed. This will be described in detail with reference to FIG. 7.

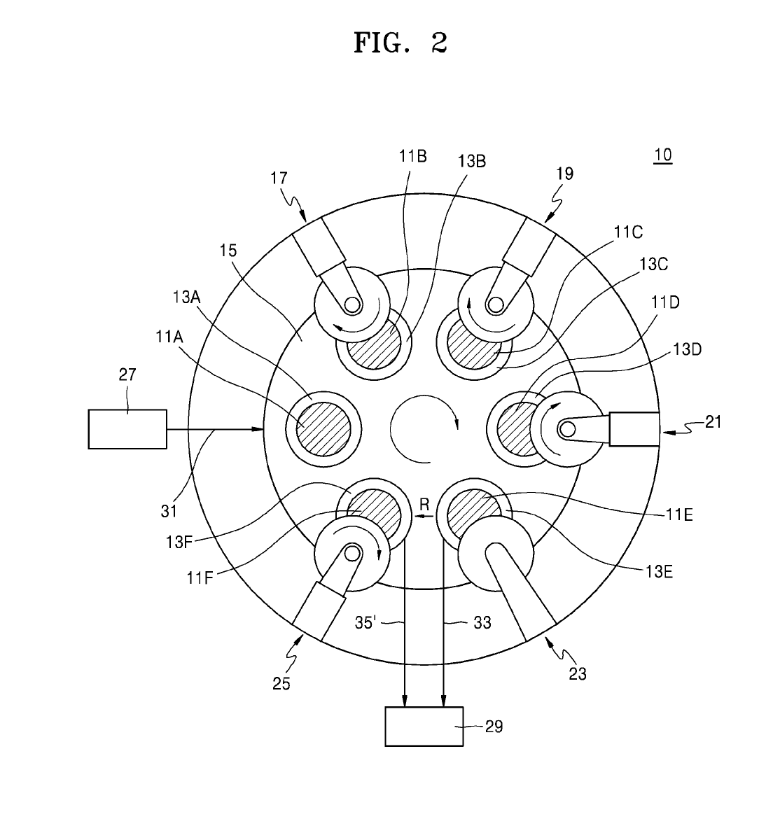

FIG. 2 is a plan view of a polishing system 10 used in the wafer backside polishing method 100 described with reference to FIG. 1.

Referring to FIG. 2, the polishing system 10 includes a turn-table 15 that includes six tables 13A through 13F on which wafers 11A through 11F are placed, and a first grinding apparatus 17, a second grinding apparatus 19, a first polishing apparatus 21, a defect metrology device 23, and a second polishing apparatus 25 which are disposed to respectively face the five tables 13B through 13F from among the six tables 13A through 13F. A wafer supply unit 27 for supplying the wafer 11A to the polishing system 10 and a wafer housing unit 29 accommodating the wafer 11F that underwent second polishing are disposed at a side of the turn-table 15.

The six tables 13A through 13F vacuum-adsorb the wafers 11A through 11F and are installed on the turn-table 15 at predetermined intervals along an edge of the turn-table 15. The six tables 13A through 13F are rotated by a certain angle according to a rotation of the turn-table 15. The six tables 13A through 13F may be classified according to a location where the tables 13A through 13F are disposed. The loaded wafers 11A through 11F standby at the standby table 13A. First grinding is performed at a first grinding table 13B. Second grinding is performed at a second grinding table 13C. First polishing is performed at a first polishing table 13D. Detection of a defect formed on a wafer backside is performed at the defect detection table 13E. Second polishing is performed at the second polishing table 13F. A period of rotation of the turn-table 15 is set with reference to a longest period of time from among periods of time taken for performing processes as the first grinding, the second grinding, the first polishing, the detection of a defect, and the second polishing.

The first and second grinding apparatuses 17 and 19 and the first and second polishing apparatuses 21 and 25 are respectively installed on the first and second grinding tables 13B and 13C and on the first and second polishing table 13D and 13F, other than the standby table 13A. The defect metrology device 23 is installed on the defect detection table 13E.

According to sequential operations of the polishing system 10 for polishing a wafer backside, a wafer 11A, on which a front-end processing has been performed, is supplied to the wafer supply unit 27 and placed on the standby table 13A by using a first conveyor 31. A backside of the wafer 11B faces upwards.

The wafer 11A placed on the standby table 13A is moved to a location of the first grinding table 13B according to a rotation of the turn-table 15. In detail, since the standby table 13A on which the wafer 11A is fixed moves below the first grinding apparatus 13A, the standby table 13A on which the wafer 11A is fixed is referred to as the first grinding table 13B. The wafer 11B on the first grinding table 13B is roughly ground by the first grinding apparatus 17 installed above the first grinding table 13B. Then, the wafer 11B, which is installed on the first grinding table 13B and on which the first grinding has been performed, is moved to a location of the second grinding table 13C according to a rotation of the turn-table 15, and thus, ground more precisely by the second grinding apparatus 19 installed above the second grinding table 13C than by the first grinding apparatus 17.

In some embodiments, a spindle motor including a diamond wheel may be used as the first grinding apparatus 17 and the second grinding apparatus 19. In this case, in some embodiments, a size of a first diamond wheel used for the first grinding apparatus 17 may be greater than a size of a second diamond wheel used for the second grinding apparatus 19.

The first and second grinding apparatuses 17 and 19 may be lowered while being rotated, and a speed of a lowering motion may vary with a wafer size.

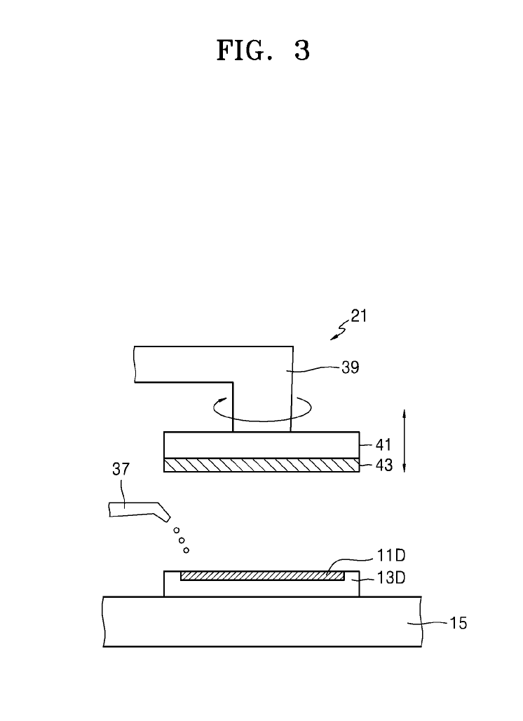

The wafer 11C, which is placed on the second grinding table 13C and on which the second grinding has been performed, is moved to a location of the first polishing table 13D according to a rotation of the turn-table 15, and thus, polished by the first polishing apparatus 21 installed above the first polishing table 13D. The first polishing apparatus 21 may be operated during the CMP. The first polishing apparatus 21 will be described in detail with reference to FIG. 3.

Although not illustrated in FIG. 2, while the polishing table 13D is moving to a location of the defect detection table 13E, the wafer 11D may be cleaned by spraying deionized water (DI) thereon by using a cleaning apparatus installed above in an area between the first polishing table 13D and the defect detection table 13E.

The wafer 11E, which is placed on the first polishing table 13E and on which the first polishing has been performed, moves to a location of the defect detection table 13E as the turn-table 15 rotates. A defect on a surface of the wafer 11E on the defect detection table 13E is measured by using the defect metrology device 23 installed above the defect detection table 13E.

The defect metrology device 23 may be equipped in the polishing system 10. In detail, an arm equipped in the polishing system 10 and a surface defect metrology device included in the arm may face the wafer backside.

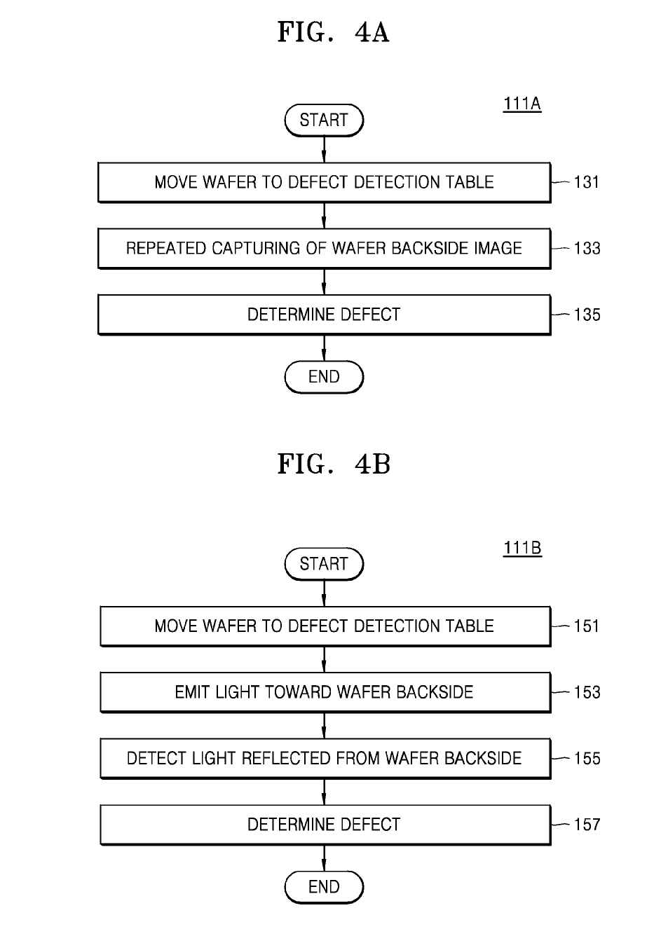

In some embodiments, the defect metrology device 23 may detecting a defect by repeatedly capturing an image of a wafer surface or by emitting light on the wafer surface and analyzing reflected light. This will be described in detail with reference to FIGS. 4A and 4B.

As described above, when a defect on the wafer backside is measured, it is determined whether a level of the defect is within an allowable range. If it is determined that the level of the defect is within the allowable range, the wafer is treated as a normal wafer and moved to the wafer housing unit 29 by using a second conveyor 33. If the level of the defect is not within an allowable range, the wafer is classified as a defective wafer and remains on the defect detection table 13E. The wafer classified as a defective wafer moves to the second polishing table 13F according to the rotation R of the turn-table 15. Then, the second polishing apparatus 25 performs second polishing on the wafer 11F on the second polishing table 13F.

The wafer 13F on which the second polishing has been performed is moved to the wafer housing unit 29 by a third conveyor 35. The wafer 13F on which the second polishing has been performed is classified as a normal wafer and is moved to the wafer housing unit 29. However, embodiments of the inventive concept are not limited thereto.

In some embodiments, a normal wafer may be moved into a wafer housing unit and a defective wafer may be moved into a defective wafer housing unit by performing the defect detection and the determining of whether a level of the defect is within an allowable range one more time after performing the second polishing. This will be described in detail with reference to FIGS. 7 through 9.

FIG. 3 is a cross-sectional view for explaining a process that corresponds to the polishing in the operations 107 and 115 in the wafer backside polishing method 100 described with reference to FIG. 1.

In FIGS. 1 and 2, the first polishing and the second polishing are described separately. However, the first polishing and the second polishing are different from each other just in view of the order of performing them and are not inherently different from each other. Accordingly, a description about polishing provided herein applies to both the first polishing and the second polishing.

FIG. 3 shows the turn-table 15, the polishing table 13D and 13F, the wafers 11D and 11f which are vacuum-adsorbed on the polishing tables 13D and 13F, a slurry feeding pipe 37 for feeding a powdered diamond slurry, and the polishing systems 21 and 25 which face the wafer 11D on the polishing tables 13D and 13F and may be raised or lowered. The polishing systems 21 and 25 include a polishing head 39 that may rotate, a polishing platen 41 connected to the polishing head 39, and a polishing pad 43 fixed to the polishing platen 41.

In detail, the wafer 11D, on which the first and second grindings described with reference to FIGS. 1 and 2 have been performed, moves to the polishing table 13D. In this case, a backside of the wafer 11D is disposed to face upwards. A slurry is fed from the slurry feeding pipe 27, and thus, coated on the whole polishing table 13D and wafer 11D. The polishing systems 21 and 25 rotate at a high speed while being lowered on the wafer 11D. Accordingly, the polishing pad 43 included in the polishing systems 21 and 25 chemical-mechanically mirror-surfaces a backside of the wafer 11D as the polishing pad 43 contacts the slurry on the wafer 11D.

FIGS. 4A and 4B are flowcharts for explaining the wafer backside defect detection 111 included in the wafer backside polishing method 100 described with reference to FIG. 1.

Referring to FIGS. 2 and 4A, in operation 131, a wafer is moved to a defect detection table so as to detect a defect. In operation 133, an image of a backside of the wafer is repeatedly captured by using a scanning camera. In operation 135, it may be determined from the images obtained by repeatedly capturing an image of the wafer backside that a defect exists at a location where a defective part regularly occurs.

Referring to FIGS. 2 and 4B, a method different from the defect detection method described with reference to FIG. 4A is described. In operation 151, a wafer is moved to a defect detection table. In operation 153, light is emitted toward a surface of the wafer. In operation 155, light reflected from the surface of the wafer is analyzed. In operation 157, a defect may be determined according to differences of reflection angles.

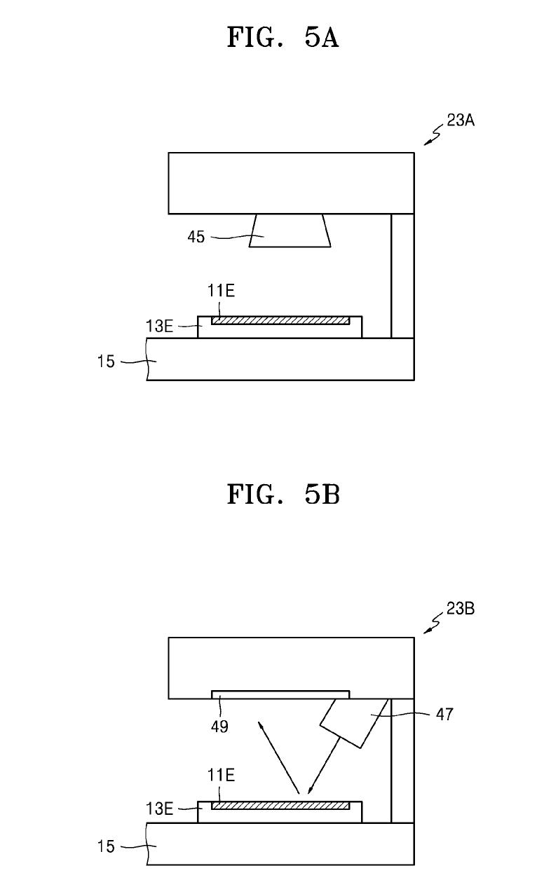

FIGS. 5A and 5B are schematic cross-sectional views of defect metrologies devices 23A and 23B used for wafer backside defect detections 111A and 111B described with reference to FIGS. 4A and 4B.

Referring to FIG. 5A, the turn-table 15, the defect detection table 13E, the wafer 11E, and the defect metrology device 23A equipped in the polishing system 10 described with reference to FIG. 2 are shown. In FIG. 5A, the defect metrology device 23A includes a camera 45 for capturing an image of a backside of the wafer 11E, and may detect a defect by using a signal processing unit.

Referring to FIG. 5B, the defect metrology device 23B includes a light-emitting device 47 and a light-receiving device 49. The defect metrology 23B may perform the defect detection by irradiating light on the wafer 11E by using the light-emitting device 47 and analyzing reflected light by using the light-receiving device 49.

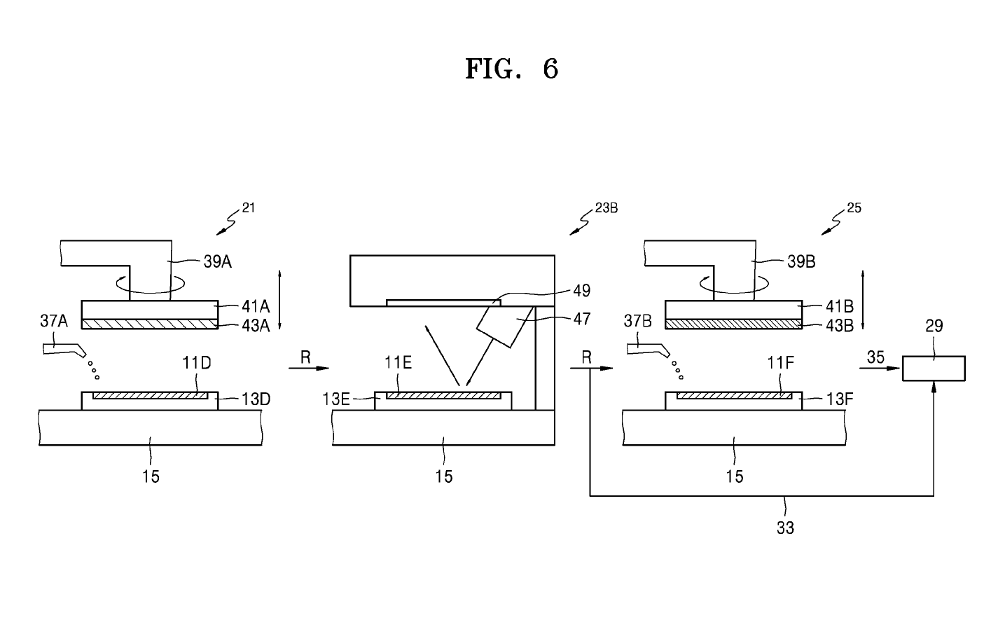

FIG. 6 is a cross-sectional view for explaining a process that corresponds to operations performed after the first polishing 107 in the wafer backside polishing method 100 described with reference to FIG. 1.

Referring to FIG. 6, a slurry fed from the slurry feeding pipe 37A is coated on the turn-table 15, the first polishing table 13D, and the wafer 11D that is vacuum-adsorbed on the polishing table 13D, and the first polishing apparatus 21 that is formed of the polishing head 39A, the polishing platen 41A, and the first polishing pad 43A is lowered and rotated, and thus, polishes the wafer 11D.

Then, the turn-table 15 performs a rotation R so that light is emitted toward a surface of the wafer 11E on the defect detection table 13E by using the light-emitting device 47. Then, light reflected from the surface of the wafer 11E is analyzed by using the light-receiving device 49, and whether a defect is present is determined according to differences of reflection angles. Although not illustrated, if a level of the defect is within an allowable range, the wafer 11E is moved to the wafer housing unit 29 by using the second conveyor 33. If a level of the defect is not within an allowable range, the wafer 11E remains on the defect detection table 13E and is moved to the second polishing table 13F according to the rotation R of the turn-table 15.

A slurry fed from the slurry feeding pipe 37B is coated on the wafer 11F that is placed on the second polishing table 13F, and the second polishing apparatus 25 that is formed of a polishing head 39B, a polishing platen 41B, and a second polishing pad 43B is lowered and rotated, and thus, polishes the wafer 11F.

Then, the wafer 11F on which the second polishing has been performed is moved to the wafer housing unit 29 by using the third conveyor 35.

In some embodiments, the first polishing apparatus 21 and the second polishing apparatus 25 respectively include the first polishing pad 43A and the second polishing pad 43B. A degree of abrasion of the first polishing pad 43A may be greater than or equal to a degree of abrasion of the second polishing pad 43B.

In some embodiments, a first polishing time taken for performing the first polishing may be different from or equal to second polishing time taken for performing the second polishing.

FIG. 7 is a flowchart for explaining a wafer backside polishing method 200 according to embodiments of the inventive concept.

Referring to FIG. 7, the wafer backside polishing method 200 is similar to the wafer backside polishing method 100 described with reference to FIG. 1. However, the wafer backside polishing method 200 further includes wafer backside defect detection in operation 201, determining whether a level of a defect is within an allowable range in operation 203, classifying a wafer as a normal wafer or a defective wafer based on a determining result, and housing the wafer in operations 205 and 207, which are performed after the second polishing in operation 115 and the wafer cleaning in operation 117 are performed.

In other words, a wafer is loaded in operation 101, first and second grindings are performed on a wafer backside in operations 103 and 105, first polishing is performed on the wafer backside in operation 107, the wafer is cleaned in operation 109, and detecting if a defect exists on the wafer backside in operation 111. Then, it is determined whether a level of the defect is within an allowable range in operation 113. If the level of the defect is within an allowable range, the wafer is unloaded into a normal wafer housing unit in operation 207. On the contrary, if the level of the defect is not within an allowable range, second polishing is performed on the wafer backside in operation 115, and the wafer is cleaned in operation 117. Then, in operation 201, it is re-detected if a defect exists on the wafer backside on which the second polishing has been performed in operation 115. In operation 203, it is re-determined whether a level of the detected defect on the wafer backside, on which the second polishing has been performed in operation 115, is within an allowable range. If the level of the defect is within the allowable range, the wafer may be unloaded into a normal wafer housing unit in operation 207. If the level of the defect is not within an allowable range, the wafer may be unloaded into a defective wafer housing unit in operation 205.

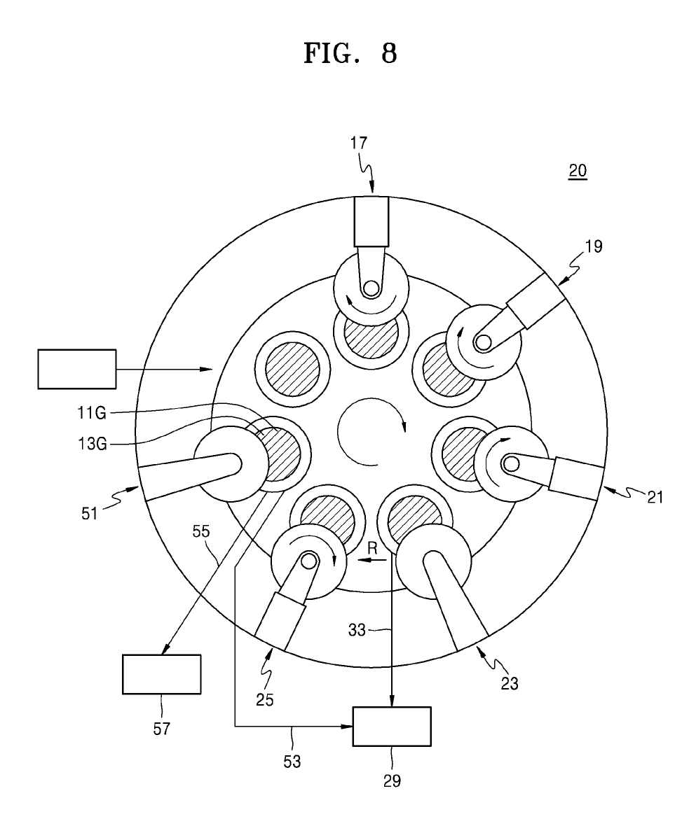

FIG. 8 is a plan view of a polishing system 20 used in the wafer backside polishing method 200 described with reference to FIG. 7.

Referring to FIG. 8, the polishing system 20 is similar to the polishing system 10 described with reference to FIG. 2. However, the polishing system 20 further includes a second defect detection table 13G and a second defect metrology 51 that is placed above the second defect detection table 13G, and equipped in the polishing system 20. If a level of a defect on the wafer 11G detected by the second defect metrology 51 is within an allowable range, the wafer 11G may be unloaded into the normal wafer housing unit 29 by using a fourth conveyor 53. If the level of the defect is not within an allowable range, the wafer 11G may be unloaded into a defective wafer housing unit 57 by using a fifth conveyor 55.

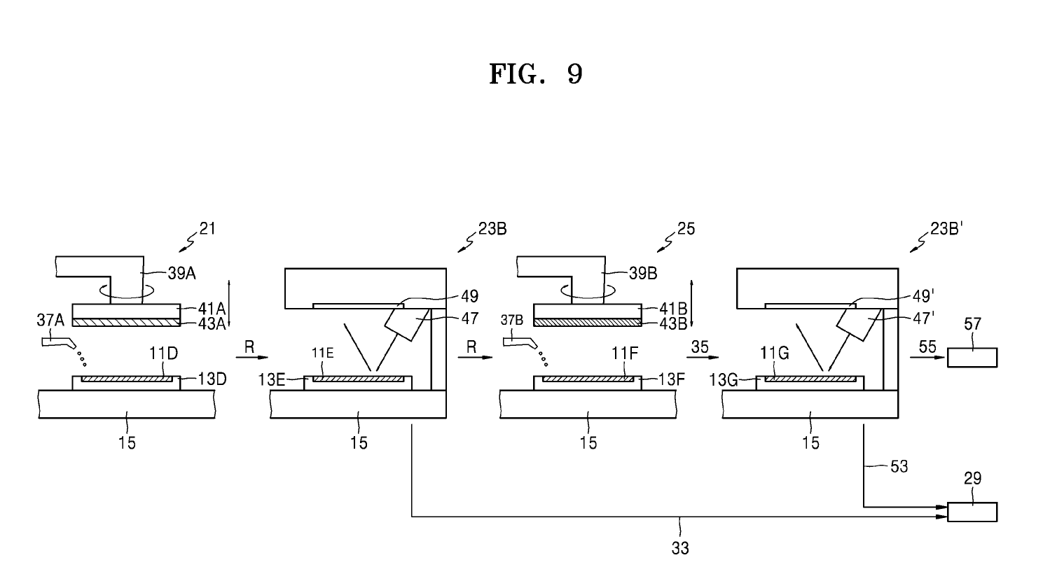

FIG. 9 is a cross-sectional view for explaining a process that corresponds to operations performed after the first polishing 107 in the wafer backside polishing method 200 described with reference to FIG. 7.

The cross-sectional view shown in FIG. 9 is similar to the cross-sectional view shown in FIG. 6. However, referring to FIG. 9, the second defect detection is further included in addition to the first polishing, the first defect detection, and the second polishing which are shown in FIG. 6. A backside of the wafer 11D is polished by using the first polishing apparatus 21, and a rotation R is performed on the turn-table 15 so as to detect if a defect exists on the backside of the wafer 11E by using a first defect metrology device 23B. If the level of a detected defect on the wafer 11D is within an allowable range, the wafer 11D is moved to the normal wafer housing unit 29 by using the second conveyor 33. If a level of the detected defect is not within an allowable range, the wafer 11D remains on the second polishing table 13F and then is moved to the defective wafer housing unit 57 according to the rotation R of the turn-table 15. Then, the backside of the wafer 11F is polished by using the second polishing apparatus 25.

Then, the rotation R is performed on the turn-table 15, and it is re-detected if a defect exists on the backside of the wafer 11G by using a second defect metrology device 23B′. The second defect metrology 23B′ includes a light-emitting device 47′ and a light-receiving device 49′. If a level of the detected defect is within an allowable range, the wafer 11E is moved to the normal wafer housing unit 29 by using the fourth conveyor 53. If a level of the detected defect is not within an allowable range, the wafer 11E is moved to the defective wafer housing unit 57 by using the fifth conveyor 55.

In FIG. 9, the first defect metrology device and the second defect metrology device are shown as being of the same type. However, embodiments of inventive concept are not limited thereto, and the first defect metrology device and the second defect metrology device may employ different defect detection methods.

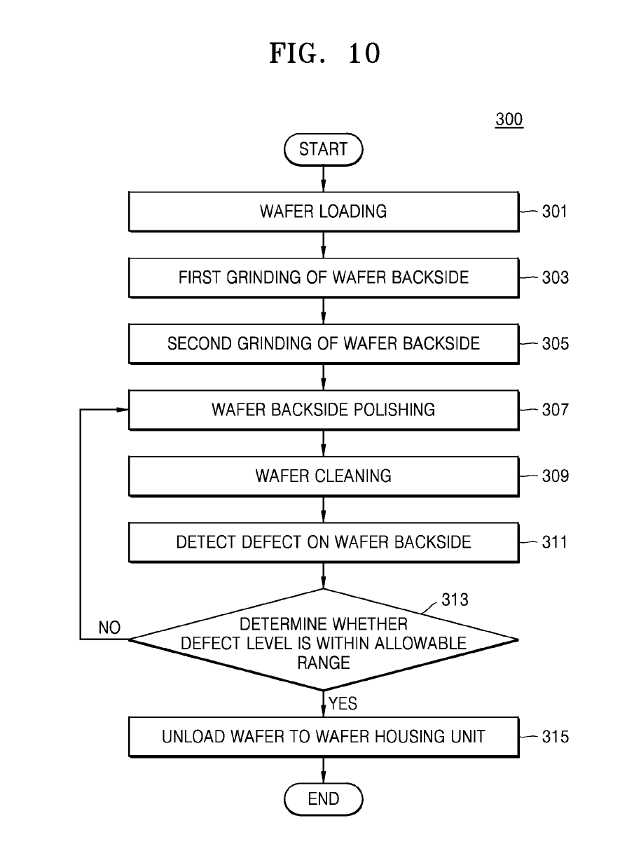

FIG. 10 is a flowchart for explaining a wafer backside polishing method 300 according to embodiments of the inventive concept.

Referring to FIG. 10, the wafer backside polishing method 300 is similar to the wafer backside polishing method 100 described with reference to FIG. 1. However, the wafer backside polishing method 300 includes repeatedly performing wafer backside polishing in operation 307, wafer cleaning in operation 309, wafer backside defect detection in operation 311, and determining whether a level of a detected defect is within an allowable range in operation 313 until the level of the defect falls within an allowable range, after performing wafer loading in operation 301, first grinding of the waver backside in operation 303, second grinding of the wafer backside in operation 305.

In some embodiments, a polishing time taken for performing the polishing may be equal to or different from re-polishing time taken for performing re-polishing. Additionally, if the re-polishing is repeatedly performed for several times, a respective re-polishing time taken for performing the respective re-polishing may be different from or equal to each other.

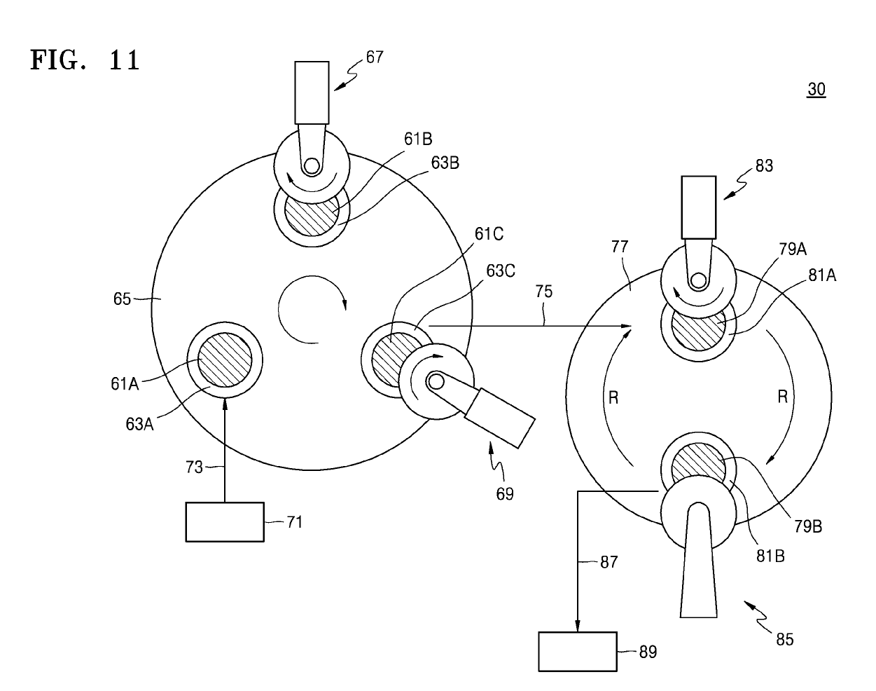

FIG. 11 is a plan view of a polishing system 30 employed in the wafer backside polishing method 300 described with reference to FIG. 10.

Referring to FIG. 11, the polishing system 30 includes a first turn-table 65 that includes three tables 63A through 63C on which wafers 61A through 61C are placed, and a first grinding apparatus 67 and a second grinding apparatus 69 which are disposed to respectively face a first grinding table 63B and a second grinding table 63C. A wafer supply unit 71 and a first conveyor 73 for supplying the wafer 61A to the standby table 63A are shown on one side of the turn-table 65. The wafer 61C on which the second grinding is finished is moved to a polishing table 81A on a second turn-table 77 by using a second conveyor 75. The wafer 79A on the polishing table 81A is mirror-surfaced by using the polishing system 83. In this case, a CMP method may be employed.

Although not illustrated in FIG. 10, the wafer 79A may be cleaned by spraying DI by using a cleaning apparatus installed above between the polishing table 81A and the defect detection table 81B.

The wafer 79A on which the polishing has been performed is moved to a location on the defect detection table 81B according to the rotation R of the turn-table 77, so that a defect on a backside of the wafer 79B is measured by the defect metrology device 85 equipped in the polishing system 30. As described above, the defect metrology device 85 equipped in the polishing system 30 may detect a defect by using various methods such as irradiating particles such as an electron beam, ion beam, light, or a neutral atom beam on a surface of the wafer 79B so that the particles interact with the surface of the wafer 79B, or by using a method such as scattering, absorption, penetration, or ionization which employ heat or an electric field.

When a defect on the backside of the wafer 79B is measured, it is determined whether a level of the defect is within an allowable range. If the level of the defect is within the allowable range, the wafer 79B is moved to the wafer housing unit 89 by the third conveyor 87. If the level of the defect is not within the allowable range, the wafer 79B is classified as a defective wafer and remains on the defect detection table 81B, and then, is moved to the polishing table 81A according to the rotation R of the turn-table 77. Then, the wafer 79A is re-polished by the polishing system 83 on the polishing table 81A.

After the re-polishing is performed, the turn-table 77 performs the rotation R, and moves to a location of the defect detection table 81B, and then, a defect on the backside of the wafer 79B is measured again by using the defect metrology device 85 equipped in the polishing system 30. A process of determining whether the level of the defect is within the allowable range set by a user and performing the re-polishing or the conveying of the wafer 79B to the wafer housing unit are repeatedly performed.

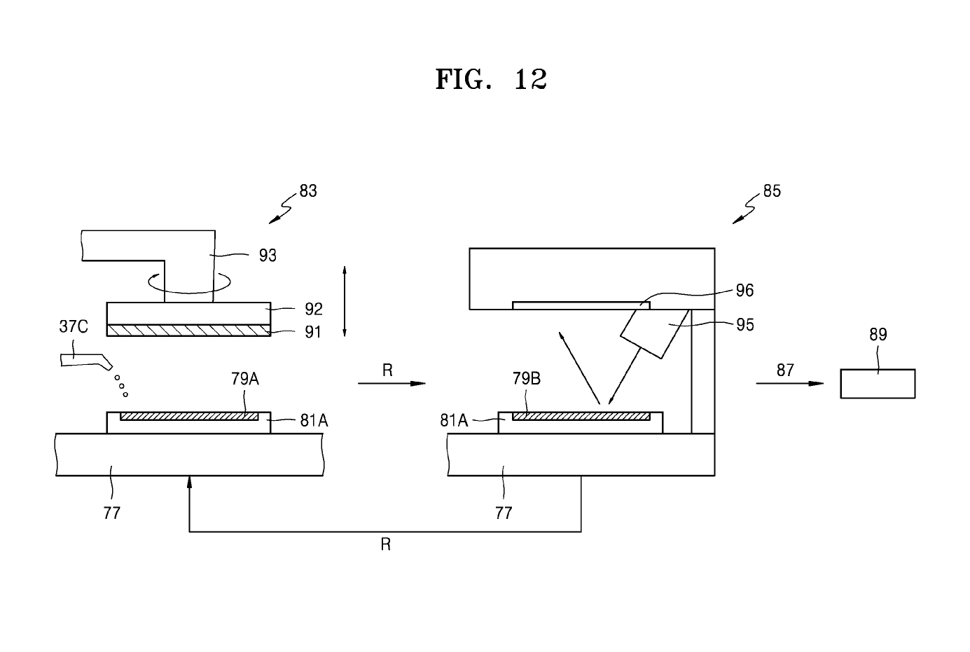

FIG. 12 is a cross-sectional view of a process that corresponds to operations performed after the polishing 307 included in the wafer backside polishing method 300 described with reference to FIG. 10.

The cross-sectional view shown in FIG. 12 is similar to the cross-sectional view shown in FIG. 6. However, with respect to the cross-section view in FIG. 12, after first polishing and first defect detection are performed, second polishing is performed by a first polishing apparatus that was employed for the first polishing, instead of using an additional apparatus, and each process is repeatedly performed by the defect metrology device 85 and the polishing system 83 until a level of the defect falls within an allowable range.

A backside of the wafer 79A is polished by the polishing system 83, a rotation R is performed on the turn-table 77, and a defect on the backside of the wafer 79B is detected by using the defect metrology device 85. If a level of the defect is within an allowable range, the wafer 79B is moved to the wafer housing unit 89 by using the third conveyor 87. If the level of the defect is not within the allowable range, the wafer 79B remains on the defect detection table 81B, is moved back to the polishing table 81A according to the rotation R of the turn-table 15, and then, is polished by the polishing system 85 on the polishing table 81A. This process is repeatedly performed until the level of the defect falls within an allowable range.

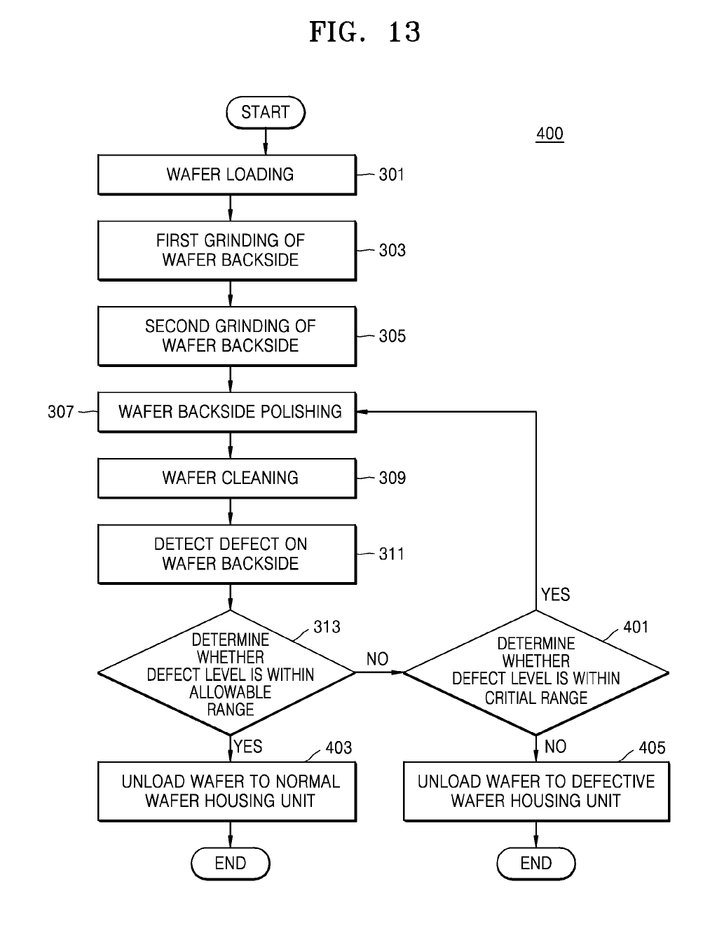

FIG. 13 is a flowchart of a wafer backside polishing method 400 according to embodiments of the inventive concept.

Referring to FIG. 13, the wafer backside polishing method 400 is similar to the wafer backside polishing method 300 described with reference to FIG. 10. However, the wafer backside polishing method 400 further includes determining whether a level of a defect is within an allowable range in operation 313, and determining whether a level of the defect is within a critical range so that the defect may be adjusted by performing re-polishing in operation 401.

The wafer loading in operation 301, the first grinding of the waver backside in operation 303, the second grinding of the wafer backside in operation 305, the wafer backside polishing in operation 307, the wafer cleaning in operation 309, and the wafer backside defect detection in operation 311 are performed. Then, if the level of the defect is within the allowable range, the wafer may be unloaded into a normal wafer housing unit in operation 403. If the level of the defect is not within the allowable range, it is determined whether the level of the defect is within the critical range so that the defect may be adjusted by performing re-polishing in operation 401. If the level of the defect is within the critical range, a subsequent process that includes the wafer backside polishing in operation 307 is performed. If the level of the defect is not within the critical range, the wafer is unloaded into a defective wafer housing unit in operation 405.

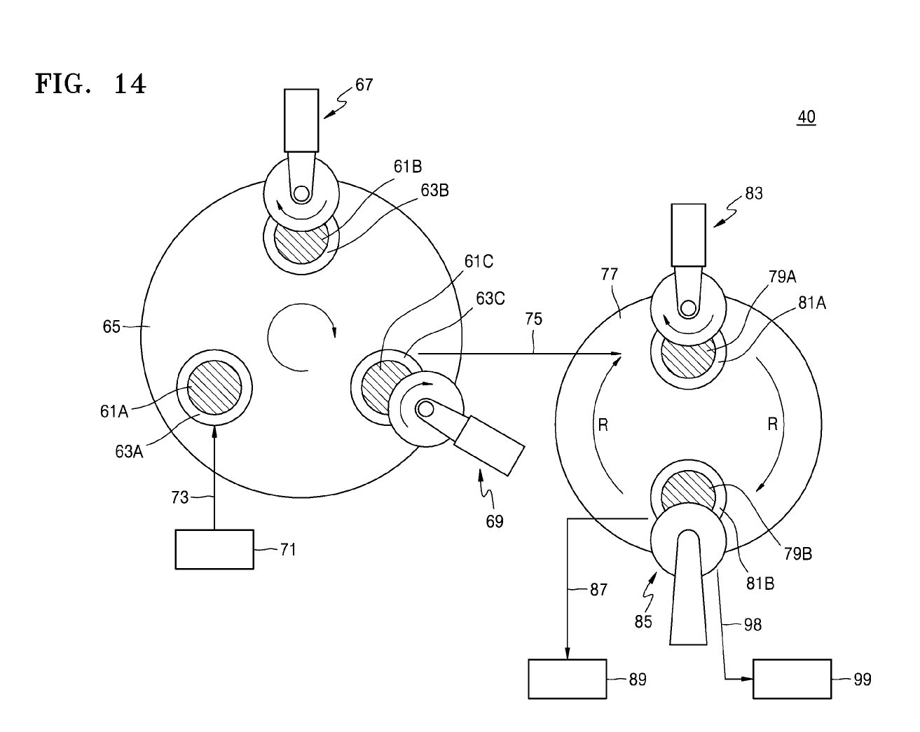

FIG. 14 is a plan view of the polishing system 40 used in the wafer backside polishing method 400 described with reference to FIG. 12.

Referring to FIG. 14, the wafer backside polishing method 400 is similar to the wafer backside polishing method 300 described with reference to FIG. 11. However, the wafer backside polishing method 400 includes determining whether a level of a defect on the wafer 79B placed on the defect detection table 81B is within a critical range so that the defect may be may be adjusted by performing re-polishing. Accordingly, if the level of the defect is within a critical range, the wafer 79B is moved to the normal wafer housing unit 89 by using the third conveyor 87. If the level of the defect is not within the critical range, the wafer 79B is moved to the defective wafer housing unit 99 by using the fourth conveyor 98. Accordingly, a wafer, which may not be corrected even by repeatedly performing the re-polishing, may be discarded in advance, and thus, a process may be performed efficiently.

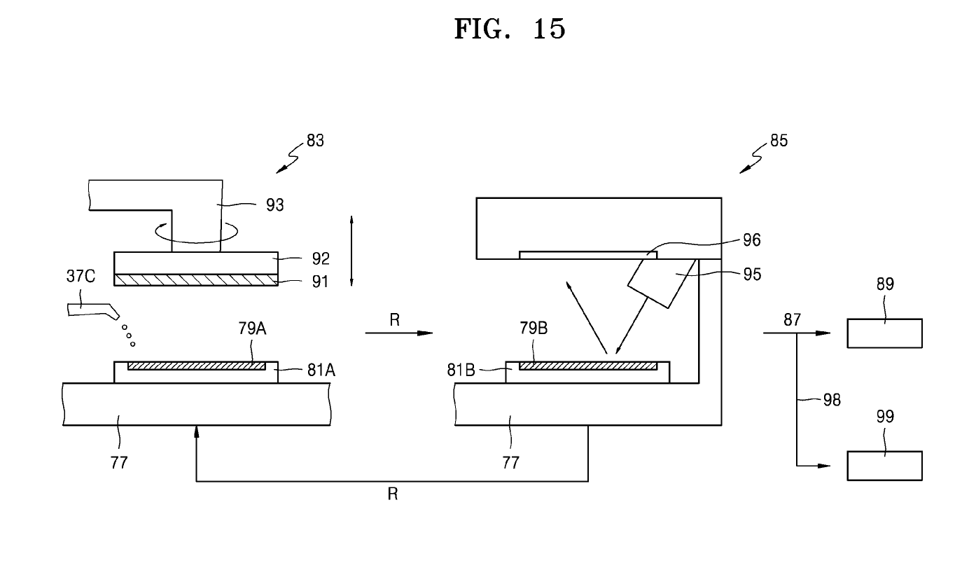

FIG. 15 is a cross-sectional view for explaining a process that corresponds to operations performed after the polishing in operation 307 included in the wafer backside polishing method 40 according to embodiments of the inventive concept.

The cross-sectional view shown in FIG. 15 is similar to the cross-sectional view shown in FIG. 12. If a level of a defect on the wafer 79B is within an allowable range, the wafer 79B is moved to the normal wafer housing unit 89 by using the third conveyor 87. If the level of the defect on the wafer 79B is not within an allowable range, the wafer 79B is moved to the defective wafer housing unit 99 by using the fourth conveyor 98.

Defects caused in grinding and polishing processes are generated on a wafer backside. Such defects may not cause a malfunction of a semiconductor device. However, in the case of a chip of a recent semiconductor device package has a thickness of 50 um or less according to demands for thin and light products, since defects on a wafer backside may affect a circuit on a front surface of the wafer, a polishing method for a wafer backside as described with reference to embodiments of the inventive concept may be required.

While the inventive concept has been particularly shown and described with reference to exemplary embodiments thereof, it will be understood that various changes in form and details may be made therein without departing from the spirit and scope of the following claims.

What is claimed is:

1. A method of wafer polishing, the method comprising:
a first polishing for polishing a wafer backside of a wafer;
detecting a defect existed on the wafer backside;
determining whether a level of the detected defect is within a first range; and
a second polishing for repolishing the wafer backside, if the level of the detected defect is not within the first range.

2. The method of claim 1, wherein the wafer is unloaded if the level of the detected defect is within the first range.

3. The method of claim 1, further comprising re-detecting a defect existed on the wafer backside of wafer after the second polishing is performed, and unloading the wafer into a normal wafer housing unit if a level of the re-detected defect is within the first range, and unloading the wafer into a defective wafer housing unit if the level of the re-detected defect is not within the first range.

4. The method of claim 1, wherein the defect is at least one of a pit, a scratch, and a particle.

5. The method of claim 1, wherein the defect is a thickness non-uniformity of a gettering layer.

6. The method of claim 1, wherein a polishing system for performing the wafer polishing method is equipped with a metrology device, and the detecting of the defect is performed by using the metrology device.

7. The method of claim 1, wherein the detecting of the defect is performed via an arm equipped in a polishing system and a metrology device installed in the arm's area facing the wafer backside.

8. The method of claim 1, wherein the detecting of the defect is performed by irradiating light on the wafer backside and analyzing reflected light.

9. The method of claim 1, wherein a first polishing apparatus for performing the first polishing and a second polishing apparatus for performing the second polishing, each comprises a first polishing pad and a second polishing pad, and a degree of abrasion of the first polishing pad is different from a degree of abrasion of the second polishing pad.

10. The method of claim 1, wherein a first polishing time taken for performing the first polishing is different from a second polishing time taken for performing the second polishing.

11. The method of claim 1, wherein a first slurry used for the first polishing is different from a second slurry used for the second polishing.

12. The method of claim 1, further comprising grinding before performing the first polishing.

13. The method of claim 12, wherein the grinding is performed for several times, and a degree of abrasion of grinding pads, used for the performing of the grinding for several times, is different from each other.

14. The method of claim 1, further comprising cleaning of the wafer after the first polishing is performed.

15. A method of wafer polishing, the method comprising:
polishing a wafer backside of a wafer received on a polishing table;
detecting a defect existed on the wafer backside;
determining whether a level of the detected defect is not within the first range; and
re-polishing the wafer backside if the level of the detected defect is not within the first range; and
repeating the detecting, the determining, and the re-polishing until it is determined that a level of a detected defect on the wafer backside is within the first range.

16. The method of claim 15, wherein the wafer is unloaded if the level of the detected defect is within the first range.

17. The method of claim 15, wherein in the repeating of the detecting, the determining, and the re-polishing, it is determined whether the level of the detected defect is within a second range so the wafer may be reprocessed into being in the first range by performing the re-polishing if it is determined that the level of the detected defect on the wafer backside is not within the first range.

18. The method of claim 15, wherein a polishing time taken for performing the polishing is different from a repolishing time taken for performing the repolishing.

19. The method of claim 15, wherein the defect is at least one selected from the group consisting of a pit, a scratch, a particle, and a thickness non-uniformity of a gettering layer.

20. A method of wafer polishing, the method comprising:
a first polishing for polishing a first wafer backside by a first polishing pad equipped in a polishing system;
detecting a defect existed on the first wafer backside by a metrology equipped in the polishing system;
determining whether a level of the detected defect is out of an allowable range; and
a second polishing for repolishing the first wafer backside by a second polishing pad equipped in the polishing system, if the level of the detected defect is out of the allowable range; and
wherein the first polishing for polishing a second wafer backside by the first polishing pad while the second polishing for repolishing the first wafer backside by the second polishing pad.
